(19) United States
(12) Patent Application Publication
(10) Pub. No.: US 2025/0323179 A1
(43) Pub. Date: Oct. 16, 2025

(54) SOLDERING SHIFT REDUCTION FOR INTEGRATED CIRCUIT PACKAGES

(71) Applicant: Analog Devices International Unlimited Company, Co. Limerick (IE)

(72) Inventors: Gerd Trampitsch, Muenchen (DE); Chuan Xu, Portland, OR (US)

(21) Appl. No.: 19/092,197

(22) Filed: Mar. 27, 2025

Related U.S. Application Data
(60) Provisional application No. 63/632,145, filed on Apr. 10, 2024.

(51) Int. Cl. H01L 23/00; H01L 23/495; H01L 25/16; H01L 25/18; H05K 1/02; H05K 1/18; H05K 3/34

(52) U.S. Cl. CPC H01L 23/562; H01L 23/49548; H01L 24/48; H01L 24/49; H01L 25/16; H01L 25/18; H05K 1/028; H01L 24/32; H01L 24/73; H01L 2224/32145; H01L 2224/32245; H01L 2224/32265; H01L 2224/48091; H01L 2224/48245; H01L 2224/49173; H01L 2224/73215; H01L 2224/73265; H01L 2225/0651; H01L 2924/19011; H05K 1/181; H05K 3/341

(57) ABSTRACT

Soldering shift reduction for packaged integrated circuits are disclosed. In certain embodiments, a packaged integrated circuit includes a paddle, a main semiconductor die having a bottom side attached to the paddle and a top side including a stress sensitive circuit fabricated thereon, and a stress cancelling die attached to the top side of the main semiconductor die. The stress cancelling die operates to provide stress cancellation that places the stress sensitive circuit at or near a stress neutral region of the package that is subject to deformation induced by the soldering process.

### CROSS-REFERENCE TO RELATED APPLICATIONS

The present application claims priority to U.S. Provisional Patent Application No. 63/632,145, filed Apr. 10, 2024, and titled “SOLDERING SHIFT REDUCTION FOR INTEGRATED CIRCUIT PACKAGES,” the entirety of which is incorporated herein by reference.

### FIELD OF THE DISCLOSURE

The field relates generally to electronics, and more particularly to packaged integrated circuits.

### BACKGROUND

Integrated circuits are typically packaged for coupling to a larger electronic system by attaching an integrated circuit die to a package substrate and encapsulating the integrated circuit die with a molding material. Some electronic circuits in the integrated circuit die may be sensitive to stress, temperature, moisture, and/or other factors that can negatively affect the performance of the electronic circuit. Packaging has been developed to protect integrated circuit dies and to facilitate connection into larger systems. However, in some situations, the packaging can negatively affect the performance of sensitive electronic circuitry.

### SUMMARY OF THE DISCLOSURE

Aspects of the disclosure relate to cancelling package stress induced by the soldering process of packaged integrated circuits. In certain embodiments, a packaged integrated circuit includes a paddle, a main semiconductor die having a bottom side attached to the paddle and a top side including a stress sensitive circuit fabricated thereon, and a stress cancelling die attached to the top side of the main semiconductor die. The stress cancelling die operates to provide stress cancellation that places the stress sensitive circuit at or near a stress neutral region of the package that is subject to deformation induced by the soldering process. Such soldering stress cancellation techniques provide a cost-effective way of reducing and/or eliminating performance degradation of packaged integrated circuits due to the soldering process.

In one aspect, an integrated circuit package includes a paddle, a main semiconductor die having a first side attached to the paddle and a second side that includes a stress sensitive circuit, and a stress cancelling die attached to the second side of the main semiconductor die. The stress cancelling die operates to provide stress cancellation arising from soldering the integrated circuit package to a circuit board.

In another aspect, an electronic system includes a circuit board and an integrated circuit package soldered to the circuit board. The integrated circuit package includes a paddle, a main semiconductor die having a first side attached to the paddle and a second side that includes a stress sensitive circuit, and a stress cancelling die attached to the second side of the main semiconductor die. The stress cancelling die operates to provide stress cancellation arising from soldering the integrated circuit package to the circuit board.

In another aspect, a method of packaging an integrated circuit includes attaching a bottom side of a main semiconductor die to a paddle, attaching a stress cancelling die to a top side of the main semiconductor die, the top side including a stress sensitive circuit, and providing stress cancellation arising from soldering the paddle to a circuit board using the stress cancelling die.

### BRIEF DESCRIPTION OF THE DRAWINGS

FIG. 1A is a schematic cross-sectional view of one example of a packaged integrated circuit.

FIG. 1B is a schematic cross-sectional view of one example of the packaged integrated circuit of FIG. 1A after soldering.

FIG. 2A is a schematic cross-sectional view a packaged integrated circuit according to one embodiment.

FIG. 2B is a schematic cross-sectional view of one example of the packaged integrated circuit of FIG. 2A after soldering.

FIG. 3 is a schematic plan view a packaged integrated circuit according to one embodiment.

FIG. 4 is a schematic circuit diagram of a stress sensitive circuit according to one embodiment.

FIG. 5 is a graph of one example of measured solder shift versus simulated solder stress.

FIG. 6A is a schematic cross-sectional view of an electronic system according to one embodiment.

FIG. 6B is a graph of one example of shift in reference voltage versus circuit board strain or bending.

FIG. 7 is a schematic cross-sectional view a packaged integrated circuit according to another embodiment.

### DETAILED DESCRIPTION

The following detailed description of embodiments presents various descriptions of specific embodiments of the invention. However, the invention can be embodied in a multitude of different ways. In this description, reference is made to the drawings where like reference numerals may indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

The mechanical stress of soldering a packaged integrated circuit (also referred to herein as a package) to a circuit board can cause package stress that leads to deformation.

For example, a packaged integrated circuit can include a semiconductor die as well as various packaging structures that each have different rates of thermal expansion and contraction. Furthermore, package deformation can occur after such a package undergoes the extreme heat of soldering (for instance, a lead-free infrared reflow profile with a peak temperature of 260° C. or higher). Inexpensive packages such as quad flat no-lead (QFN) packages in particular exhibit large package warpage due to mechanical deformation after the soldering process.

Package deformation can degrade the performance of packaged integrated circuits that include stress sensitive circuits, such as voltage references. For example, warpage in a packaged integrated circuit that includes a voltage reference (such as a bandgap reference circuit) can cause the output reference voltage to shift after soldering.

Various embodiments disclosed herein relate to cancelling package stress induced by the soldering process of packaged integrated circuits. In certain embodiments, a packaged integrated circuit includes a paddle, a main semiconductor die having a bottom side attached to the paddle and a top side including a stress sensitive circuit fabricated thereon, and a stress cancelling die attached to the top side of the main semiconductor die. The stress cancelling die operates to provide stress cancellation that places the stress sensitive circuit at or near a stress neutral region of the package that is subject to deformation induced by the soldering process.

In certain implementations, the stress cancelling die is implemented as a thick dummy die that is much thicker than a thin main die that includes stress sensitive circuitry. The stack of the paddle, thin main die, and thick dummy die can result in the location of stress sensitive circuits being closer to the stress neutral region.

For example, the stress neutral region can correspond to one or more points and/or axis where tensile and compressive stress cancel each other in a deformed beam. Additionally, the dummy die and main die can form a complex that approximates the behavior of a single beam. When the dummy die and the main die are formed from a common material (for example, a semiconductor, such as silicon), both have the same coefficient of thermal expansion (CTE). Moreover, the dummy die shields the main die from global and local mold compound stress, while local stress is mainly due to particles (for instance, silica particles) in the mold compound.

The soldering stress cancellation techniques herein provide a cost-effective way of reducing and/or eliminating performance degradation of packaged integrated circuits due to the soldering process.

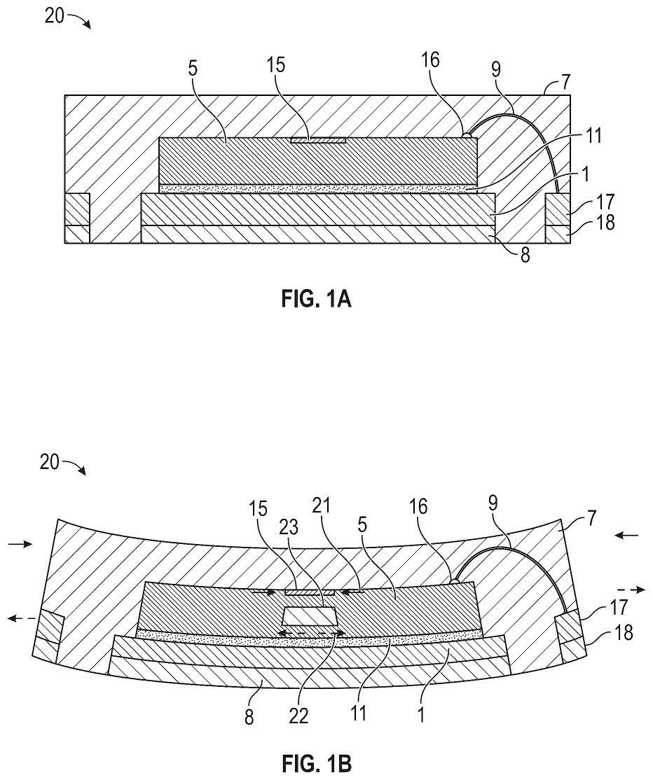

FIG. 1A is a schematic cross-sectional view of one example of a packaged integrated circuit 20. The packaged integrated circuit 20 includes a paddle 1, a semiconductor die 5, a molding material or encapsulation 7, a paddle solder region 8, a bond wire 9, a die attach 11, a die pad 16, a package lead 17, and a package lead solder region 18.

As shown in FIG. 1A, the semiconductor die 5 includes a stress sensitive circuit 15 fabricated thereon.

FIG. 1B is a schematic cross-sectional view of one example of the packaged integrated circuit 20 of FIG. 1A after soldering.

As shown in FIG. 1B, the extreme heat of the soldering process has resulted in deformation or warpage of the packaged integrated circuit 20.

The deformation of the packaged integrated circuit 20 can arise from the semiconductor die 5 and various packaging structures (for example, the paddle 1 and/or the molding material 7) each having different rates of thermal expansion and contraction.

The varying rates of thermal expansion and contraction can lead to a compressive force 21 near the top of the semiconductor die 5 and a tensile force 22 near the bottom of the semiconductor die 5.

As shown in FIG. 1B, a stress neutral region 23 is away from the stress sensitive circuit 15. In one example, the stress sensitive circuit 15 is a bandgap reference circuit that outputs an absolute voltage. The deformation imparted on such a bandgap reference circuit can cause unacceptable shifts in the output voltage that deteriorate the overall performance of the packaged integrated circuit 20.

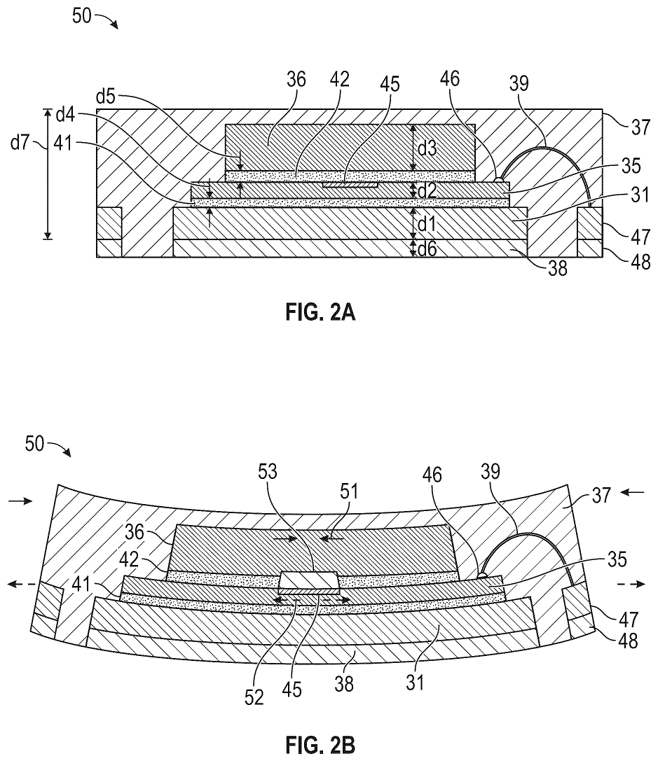

FIG. 2A is a schematic cross-sectional view a packaged integrated circuit 50 according to one embodiment. The packaged integrated circuit 50 includes a paddle 31, a main semiconductor die 35, a stress cancelling die 36, a molding material 37, a paddle solder region 38, a bond wire 39, a first die attach 41, a second die attach 42, a die pad 46, a package lead 47, and a package lead solder region 48.

As shown in FIG. 2A, the main semiconductor die 35 includes a stress sensitive circuit 45 fabricated on a top side or active side of the die 35. Additionally, a bottom side or inactive side of the main semiconductor die 35 is attached to the paddle 31 by way of the first die attach 41, which can be, for example, a conductive or non-conductive epoxy. The paddle 31 can be, for example, an exposed copper paddle. The paddle 31 aids in providing thermal dissipation during operation.

With continuing reference to FIG. 2A, the stress cancelling die 36 is attached to the top side of the main semiconductor die 35 by way of a second die attach 42. The second die attach 42 can be any suitable material for providing die attachment and can be the same or different material as the first die attach 41.

As shown in FIG. 2A, the molding material 37 is formed over the stack of the paddle 31, main semiconductor die 35, and stress cancelling die 36. The molding material 37 aids in protecting the semiconductor dies during use. In certain implementations, the molding material 37 can include a plastic material that includes an epoxy molding compound, for example, a resin.

In the embodiment of FIG. 2A, the die pad 46 of the main semiconductor die 35 is electrically coupled to the package lead 47 by way of the bond wire 39. The bond wire 39 can be made of any suitable conductive material, such as gold or copper. Although only one attachment between the main semiconductor die 35 and the lead frame of the package is shown, typically many bond wires are used to attach several die pads to leads of the lead frame.

Although the main semiconductor die 35 is wire bonded in FIG. 2A to package leads of a lead frame, it should be appreciated that the main semiconductor die 35 can be electrically connected in other ways. For example, in some embodiments (such as those that utilize a printed circuit board for a package substrate), the main semiconductor die 35 can be attached (for instance, soldered) to the package substrate, and internal traces within the package substrate can provide electrical communication between the main semiconductor die 35 and an external circuit board. The main semiconductor die 35 can also be flip chip mounted and coupled to the package substrate in some embodiments. In still other arrangements, the main semiconductor die 35 can be electrically coupled to the package substrate using non-conductive paste (NCP) or anisotropic conductive film (ACF) technologies.

Thus, the teachings herein are applicable to a wide range of types of packages. Thus, not only are the teachings herein applicable to QFN packages, but to other types of packages as well, such as low profile quad flat pack (LQFP) packages, ball grid array (BGA) packages, as well as to other types of packages, including those that use flip chip technologies.

Moreover, other configurations of stacking are possible. In one embodiment, the paddle 31 is above the main semiconductor die 35, and the main semiconductor die 35 is above the stress cancelling die 36.

In FIG. 2A, the stress sensitive circuit 45 is schematically depicted. However, a skilled artisan would understand that the stress sensitive circuit 45 can be fabricated from layers of the main semiconductor die 35. The stress sensitive circuit 45 can be a precision component having a performance degraded by stresses, as opposed to a circuit that outputs or measures relative voltages and that is not stress sensitive. Examples of the stress sensitive circuit 45 include, but are not limited to, a reference circuit (a current reference or a voltage reference, such as bandgap reference circuit), an oscillator, a sensor, a data converter (for example, a digital-to-analog converter or an analog-to-digital converter), and/or an amplifier. Such stress sensitive circuitry can include one or more stress sensitive components, such as stress sensitive transistors, resistor, capacitors, and/or matching structures.

In certain implementations, the main semiconductor die 35 is a battery management system (BMS) integrated circuit (IC) that includes battery management circuitry that uses the stress sensitive circuit 45 to operate. For example, the stress sensitive circuit 45 can include a bandgap reference circuit that provides a bandgap reference voltage to the battery management circuitry of the BMS IC.

As shown in FIG. 2A, solder is placed along a bottom side of the packaged integrated circuit 50 and is used for making electrical connections to a circuit board (not shown in FIG. 2A) to which the packaged integrated circuit 50 can be attached for operation in a larger electronic system. For example, the paddle solder region 38 is provided for the paddle 31, while the package lead solder region 48 is provided for the package lead 47 as well as other leads of the lead frame.

The mechanical stress of soldering the packaged integrated circuit 50 on a circuit board (for example, a printed circuit board or PCB) can cause package stress that leads to deformation of the packaged integrated circuit 50.

As shown in FIG. 2A, the stress cancelling die 36 is placed over the top side of the main semiconductor die 35. The stack of the paddle 31, main semiconductor die 35, and stress cancelling die 36 can result in the location of the stress sensitive circuit 45 being closer to a stress neutral region after soldering. In certain implementations, the stress cancelling die 36 is chosen to have the same material (for example, a semiconductor, such as silicon) as the main semiconductor die 35 such that both dies have the same CTE.

Although the stress cancelling die 36 can be a semiconductor die, the teachings herein also applicable to implementations in which the stress cancelling die 36 is not a semiconductor.

In the illustrated embodiment, the stress cancelling die 36 also fully covers the stress sensitive circuit 45, which prevents the mold material 37 from touching the upper surface of the main semiconductor die 35 near where the stress sensitive circuit 45 is fabricated. Since particles (for example, silica particles) in the mold material 37 can induce local stresses, implementing the stress cancelling die 36 to fully cover the stress sensitive circuit 45 provides a performance enhancement by reducing the impact of local stresses on performance of the stress sensitive circuit 45.

Various thickness dimensions of components of the packaged integrated circuit 50 have been schematically annotated in FIG. 2A. For example, the paddle 31 has a thickness d1, the main semiconductor die 35 has a thickness d2, the stress cancelling die 36 has a thickness d3, the first die attach 41 has a thickness d4, the second die attach 42 has a thickness d5, the solder has a thickness d6, and the molding material 37 has a thickness d7.

The thicknesses can be of any suitable values. In certain implementations, the thickness d1 is selected to be in the range of 100 μm to 400 μm (or more particularly, in the range of 160 μm to 240 μm), for example, 200 μm. In some implementations, the thickness d2 is selected to be in the range of 80 μm to 120 μm, for example, 100 μm. In various implementations, the thickness d3 is selected to be in the range of 80 μm to 700 μm (or more particularly, in the range of 200 μm to 300 μm), for example, 250 μm. In certain implementations, the thicknesses d4 and d5 are selected to be less than 50 μm, for example 20 μm. In some implementations, the thickness d6 is selected to be in the range of 50 μm to 75 μm, for example, 63 μm. In various implementations, the thickness d7 is selected to be in the range of 600 μm to 900 μm, for example, 750 μm.

Although example thickness ranges have been provided, other values of thickness can be used.

In certain implementations, the stress cancelling die 36 is implemented as a thick dummy die and the main semiconductor die 35 is implemented as a thin main die that includes the stress sensitive circuit 45. For example, in some implementations, the stress cancelling die 36 is between 0.5 and 10 times (or more particularly, between 1.5 and 5 times) the thickness of the main semiconductor die 35.

In implementations in which the stress cancelling die 36 is a dummy die, the stress cancelling die 36 does not include any operative circuitry. In other implementations, the stress cancelling die 36 includes circuits that operate in combination with the circuitry of the main semiconductor die 35 (including the stress sensitive circuit 45) to achieve a desired overall functionality of the packaged integrated circuit 50.

In some embodiments, the stress cancelling die 36 has a thickness selected that is roughly about that of the paddle 31. For example, in certain implementations, the thickness of the stress cancelling die 36 is within about 50% to 150% the thickness of the paddle 31.

Although one main semiconductor die 35 is attached to the paddle 31 in FIG. 2A, in other embodiments one or more additional main semiconductor dies can also be attached to the paddle 31. Such additional main semiconductor dies can be implemented with or without stress cancelling die(s) for stress cancellation.

FIG. 2B is a schematic cross-sectional view of one example of the packaged integrated circuit 50 of FIG. 2A after soldering.

As shown in FIG. 2B, the extreme heat of the soldering process has resulted in deformation or warpage of the packaged integrated circuit 50. For example, the varying rates of thermal expansion and contraction can lead a compressive force 51 near the top of the stress cancelling die 36 and a tensile force 52 near the bottom of the main semiconductor die 35.

However, in comparison to the warped packaged integrated circuit 20 of FIG. 1B in which the stress neutral region 23 is far away from the stress sensitive circuit 15, the warped packaged integrated circuit 50 of FIG. 2B includes a stress neutral region 53 that is at or near the stress sensitive circuit 45.

In certain implementations, the stress cancelling die 36 provides stress cancellation that results in the stress neutral region 23 being not exactly at the location of the stress sensitive circuit 45 and only reduces the stress level at stress sensitive circuit 45.

In some embodiments, the stress differential due to the soldering process is substantially minimized by moving a stress neutral point closer to the sensitive circuitry. Additionally or alternatively, in certain embodiments the stress cancelling die positions a stress neutral region after soldering to within 100 μm of the stress sensitive circuit.

Thus, the stress cancelling die 36 and the main semiconductor die 35 can form a complex that approximates the behavior of a single beam. Furthermore, in implementations in which the stress cancelling die 36 and the main semiconductor die 35 are formed from a common material (for example, a semiconductor, such as silicon) they both have the same CTE. Moreover, the stress cancelling die 36 shields the main semiconductor die 35 from global and local stresses of the mold material 37, while local stress is mainly due to particles (for instance, silica particles) in the mold material 37.

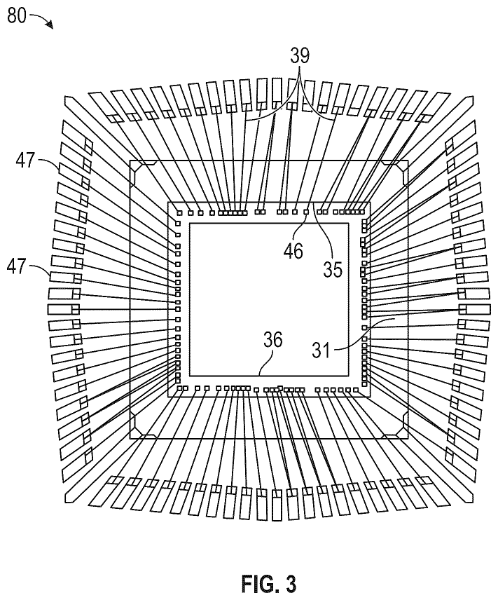

FIG. 3 is a schematic plan view a packaged integrated circuit 80 according to one embodiment. The packaged integrated circuit 80 is implemented as a QFN package that includes a lead frame that includes leads 47. Additionally, a main semiconductor die 31 is attached to a paddle 31 (for example, an exposed copper paddle), while a stress cancelling die 36 is attached over the main semiconductor die 31. The main semiconductor die 31 includes pads 46 that attach to the leads 47 of the lead frame by way of bond wires 39. The main semiconductor die 31 includes stress sensitive circuitry, such as a bandgap reference voltage.

As shown in FIG. 3, the leads 47 can surround and be electrically isolated from the paddle 31 (or, in another implementation, fused to the paddle 31). The pads 46 can be formed around the perimeter of the main semiconductor die 35, and the stress cancelling die 36 can leave the pads 46 exposed to enable wire bonding of the bonding wires 39 to the leads 47. In some implementations, the stress cancelling die 36 covers about 50% to about 90% of the top surface of the main semiconductor die 35. In certain implementations, the stress cancelling die 36 fully covers the stress sensitive circuitry of the main semiconductor die 35 to protect the stress sensitive circuitry from global and local stresses of a mold material (not shown in FIG. 3 for clarity of the figure).

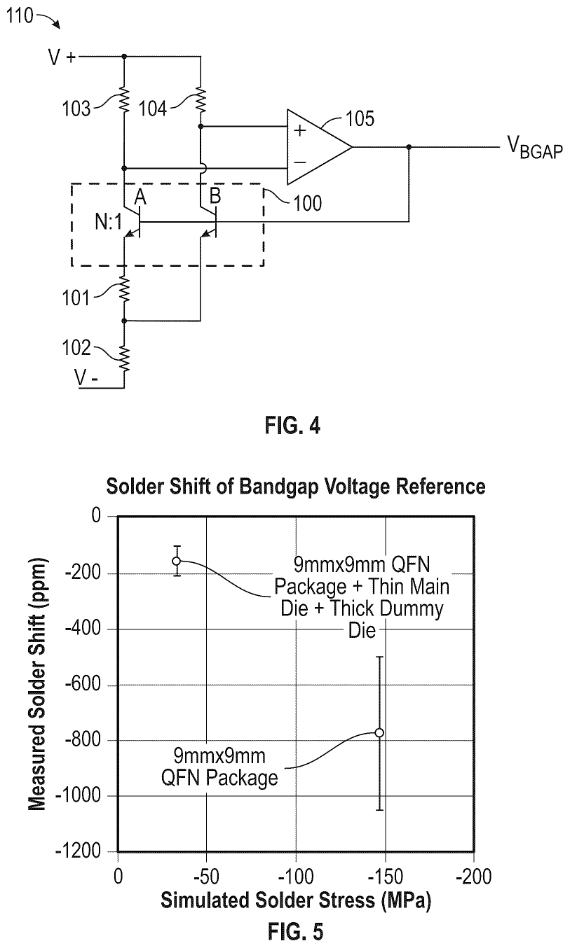

FIG. 4 is a schematic circuit diagram of a stress sensitive circuit 110 according to one embodiment. The stress sensitive circuit 110 corresponds to a bandgap reference circuit, in this embodiment.

Although the stress sensitive circuit 110 depicts one example of a stress sensitive circuit that can be included in a packaged integrated circuit, the packaged integrated circuits herein can include other types of stress sensitive circuits. For instance, examples of a stress sensitive circuit include, but are not limited to, a reference circuit (a current reference or a voltage reference, such as bandgap reference circuit), an oscillator, a sensor, a data converter (for example, a digital-to-analog converter or an analog-to-digital converter), and/or an amplifier.

In the illustrated embodiment, the stress sensitive circuit 110 includes a pair of ratioed bipolar transistors 100, a first resistor 101, a second resistor 102, a third resistor 103, a fourth resistor 104, and an amplifier 105. The stress sensitive circuit 110 receives a first voltage V+ and a second voltage V−, which in some implementations correspond to a power supply voltage and a ground voltage, respectively. The stress sensitive circuit 110 also outputs a bandgap voltage V_{BGAP}, which is desired to be substantially constant even in the presence of package warpage arising from soldering.

With continuing reference to FIG. 4, the pair of ratioed bipolar transistors 100 includes a first NPN bipolar transistor A and a second NPN bipolar transistor B that are electrically coupled to an inverted input and a non-inverted input, respectively, of the amplifier 105. For example, the first NPN bipolar transistor A includes a collector connected to the inverted input of the amplifier 105, while the second NPN bipolar transistor B includes a collector connected to the non-inverted input of the amplifier 105.

As shown in FIG. 4, the output of the amplifier 105 provides the bandgap voltage V_{BGAP} and is also connected to the base of the first NPN bipolar transistor A and to the base of the second NPN bipolar transistor B. The inverted input of the amplifier 105 is also connected to the first voltage V+ through the third resistor 103, while the non-inverted input of the amplifier 105 is also connected to the first voltage V+ through the fourth resistor 104. The emitter of the first NPN bipolar transistor A is connected to the second voltage V− through the series combination of the first resistor 101 and the second resistor 102, while the emitter of the second NPN bipolar transistor B is connected to the second voltage V− through the second resistor 102.

With continuing reference to FIG. 4, the first NPN bipolar transistor A has a larger area than the second NPN bipolar transistor B. For example, as illustrated, the ratio of emitter areas of the first NPN bipolar transistor A to the second NPN bipolar transistor B can be N:1, where N can be, for example, at least 2.

The stability of the bandgap voltage V_{BGAP} can depend on the electrical characteristics associated with a precise ratio of the emitter area of the first NPN bipolar transistor A to the emitter area of the second NPN bipolar transistor B. However, electrical characteristics of the first and the second NPN bipolar transistors A and B may be affected by mechanical stresses resulting from package deformation.

Thus, stresses imparted on the stress sensitive circuit 110 may cause an unacceptable voltage shift in the bandgap voltage V_{BGAP} that reduces the performance of an electronic system that operates based on the bandgap voltage V_{BGAP}.

FIG. 5 is a graph of one example of measured solder shift versus simulated solder stress. The graph compares variation in solder shift of bandgap voltage for a 9×9 mm QFN package in accordance with one implementation of the packaged integrated circuit 20 of FIG. 1A after soldering versus a 9×9 mm QFN package in accordance with one implementation of the packaged integrated circuit 50 of FIG. 2A after soldering.

As shown in FIG. 5, the use of a thick dummy die to provide stress cancellation results in statistically much less solder shift of the bandgap voltage.

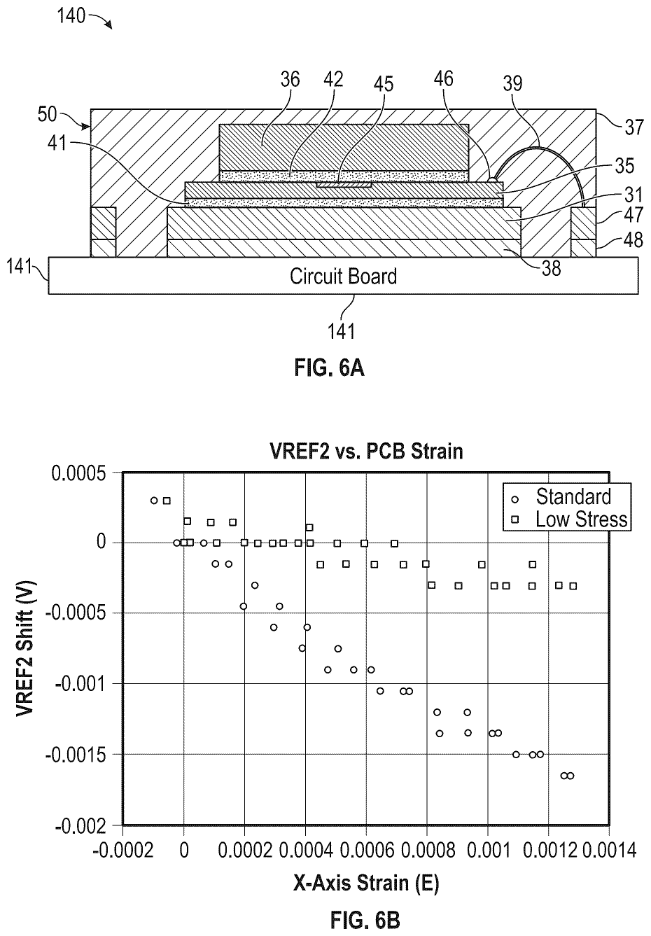

FIG. 6A is a schematic cross-sectional view of an electronic system 140 according to one embodiment. The electronic system 140 includes a circuit board 141 and a packaged integrated circuit 50 attached to the circuit board 141.

The electronic system 150 of FIG. 6A depicts an example of the packaged integrated circuit 50 of FIG. 2A after soldering to the circuit board 141. The packaged integrated circuit 50 exhibits better reference stability when bending the circuit board 141 due to the inclusion of the stress cancelling die 36. For example, bending the circuit board 141 deforms the packaged integrated circuit 50, but the deformation matters less when the reference is in a stress neutral position.

FIG. 6B is a graph of one example of shift in reference voltage versus circuit board strain or bending. As shown in FIG. 6B, the shift in reference voltage is compared for a packaged integrated circuit with a stress cancelling die relative to a packaged integrated circuit without a stress cancelling die. The packaged integrated circuit with the stress cancelling die exhibits better reference stability when bending the circuit board.

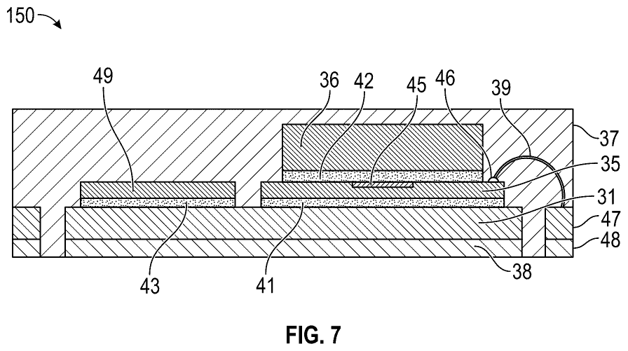

FIG. 7 is a schematic cross-sectional view a packaged integrated circuit 150 according to another embodiment. The packaged integrated circuit 150 of FIG. 7 is similar to the packaged integrated circuit 50 of FIG. 2A, except that the packaged integrated circuit 150 further includes a third die attach 43 and an additional main semiconductor die 49 that does not include a stress cancelling semiconductor die, in this example. However, in another embodiment, a stress cancelling die is also included over the additional main semiconductor die 49.

Any number of semiconductor dies can be included in the packaged integrated circuits disclosed herein.

### CONCLUSION

The foregoing description may refer to elements or features as being “connected” or “coupled” together. As used herein, unless expressly stated otherwise, “connected” means that one element/feature is directly or indirectly connected to another element/feature, and not necessarily mechanically. Likewise, unless expressly stated otherwise, “coupled” means that one element/feature is directly or indirectly coupled to another element/feature, and not necessarily mechanically. Thus, although the various schematics shown in the figures depict example arrangements of elements and components, additional intervening elements, devices, features, or components may be present in an actual embodiment (assuming that the functionality of the depicted circuits is not adversely affected).

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while the disclosed embodiments are presented in a given arrangement, alternative embodiments may perform similar functionalities with different components and/or circuit topologies, and some elements may be deleted, moved, added, subdivided, combined, and/or modified. Each of these elements may be implemented in a variety of different ways. Any suitable combination of the elements and acts of the various embodiments described above can be combined to provide further embodiments. Accordingly, the scope of the present invention is defined only by reference to the appended claims.

Although the claims presented here are in single dependency format for filing at the USPTO, it is to be understood that any claim may depend on any preceding claim of the same type except when that is clearly not technically feasible.

1. An integrated circuit package, comprising:
a paddle;
a main semiconductor die having a first side attached to the paddle and a second side that includes a stress sensitive circuit; and
a stress cancelling die attached to the second side of the main semiconductor die, wherein the stress cancelling die operates to provide stress cancellation arising from soldering the integrated circuit package to a circuit board.

2. The integrated circuit package of claim 1, wherein the stress cancelling die positions a stress neutral region after soldering to within 100 μm of the stress sensitive circuit.

3. The integrated circuit package of claim 1, wherein a stress differential due to a soldering process is substantially minimized by moving a stress neutral point closer to the stress sensitive circuit.

4. The integrated circuit package of claim 1, further comprising a molding material over the stress cancelling die, the main semiconductor die, and the paddle.

5. The integrated circuit package of claim 1, wherein the stress cancelling die fully covers a portion of the main semiconductor die that includes the stress sensitive circuitry.

6. The integrated circuit package of claim 1, wherein the stress cancelling die leaves a plurality of pads of the main semiconductor die exposed for wire bonding.

7. The integrated circuit package of claim 6, further comprising a lead frame including a plurality of leads, and plurality of bond wires electrically coupling the plurality of leads to the plurality of pads of the main semiconductor die.

8. The integrated circuit package of claim 1, wherein the stress sensitive circuit comprises a bandgap reference circuit.

9. The integrated circuit package of claim 1, wherein the stress cancelling die has a thickness that is a factor of 0.5 to 10 times a thickness of the main semiconductor die.

10. The integrated circuit package of claim 1, wherein the stress cancelling die has a thickness in a range of 80 μm to 700 μm and the main semiconductor die has a thickness in a range of 80 μm to 120 μm.

11. The integrated circuit package of claim 10, wherein the paddle has a thickness in a range of 100 μm to 400 μm.

12. The integrated circuit package of claim 1, wherein the stress cancelling die is a dummy die or includes operative circuitry.

13. The integrated circuit package of claim 1, wherein the main semiconductor die and the stress cancelling die are formed of a common material to provide a common coefficient of thermal explanation (CTE).

14. The integrated circuit package of claim 13, wherein the common material is silicon.

15. The integrated circuit package of claim 1, implemented in a quad flat no-lead (QFN) package.

16. The integrated circuit package of claim 1, further comprising at least one additional main semiconductor die on the paddle.

17. The integrated circuit package of claim 16, wherein the at least one additional main semiconductor die is not stacked with any stress cancelling die.

18. (canceled)

19. (canceled)

20. (canceled)

21. (canceled)

22. (canceled)

23. (canceled)

24. (canceled)

25. An electronic system comprising:
a circuit board; and
an integrated circuit package soldered to the circuit board, the integrated circuit package comprising:
a paddle;
a main semiconductor die having a first side attached to the paddle and a second side that includes a stress sensitive circuit; and
a stress cancelling die attached to the second side of the main semiconductor die, wherein the stress cancelling die operates to provide stress cancellation arising from soldering the integrated circuit package to the circuit board.

26. (canceled)

27. The electronic system of claim 25 wherein the stress cancellation provided by the stress cancelling die counteracts a stress effect due to bending of the circuit board.

28. A method of packaging an integrated circuit, the method comprising:
attaching a bottom side of a main semiconductor die to a paddle;
attaching a stress cancelling die to a top side of the main semiconductor die, the top side including a stress sensitive circuit; and
providing stress cancellation arising from soldering the paddle to a circuit board using the stress cancelling die.

29. (canceled)
